(19) United States
(12) Patent Application Publication
(10) Pub. No.: US 2018/0210301 A1
(43) Pub. Date: Jul. 26, 2018

(54) LIQUID CRYSTAL PANEL AND LIQUID CRYSTAL DISPLAY APPARATUS

(71) Applicant: SHENZHEN CHINA STAR OPTOELECTRONICS TECHNOLOGY CO., LTD., Guangdong (CN)

(72) Inventors: Jingjing WU, Shenzhen, Guangdong (CN); Dekang ZENG, Shenzhen, Guangdong (CN)

(73) Assignee: Shenzhen China Star Optoelectronics Technology Co., Ltd., Shenzhen, Guangdong (CN)

(21) Appl. No.: 15/315,718

(22) PCT Filed: Sep. 27, 2016
(86) PCT No.: PCT/CN2016/100322

§ 371 Date: Dec. 1, 2016

(30) Foreign Application Priority Data
Aug. 31, 2016 (CN) 201610794188.0

(51) Int. Cl. G02F 1/1362; G02F 1/1368; H01L 27/12

(52) U.S. Cl. CPC G02F 1/136286; H01L 27/124; G02F 1/136213; G02F 1/1368

(57) ABSTRACT

The present application discloses a liquid crystal panel includes a plurality of gate lines extending in the row direction and are parallel to each other; a plurality of data lines extending in the column direction and are parallel to each other, wherein the gate line and the data line are cross disposed; a sub-pixel is disposed at the intersection of each gate line and each data line; a switching thin-film transistor disposed between each of the odd sub-pixels and the even sub-pixels adjacent to each other on each row; the odd sub-pixels is the sub-pixels located in the odd columns; the even sub-pixels is the sub-pixels located in the even columns; wherein a gate electrode is connected to the corresponding gate line of the previous pixel row, a drain electrode is connected to the corresponding odd sub-pixel, and a source electrode is connected to the corresponding even sub-pixel.

### FIELD OF THE INVENTION

The present application relates to a liquid crystal display apparatus technology field, and more particularly to a liquid crystal panel and liquid crystal display apparatus.

### BACKGROUND OF THE INVENTION

A normal display of image from a liquid crystal panel is achieved by turning on scanning lines row by row to load the needed voltage through data line. In order to prevent the DC blocking effect and DC residue of the liquid crystal panel, it is necessary to apply AC voltage across the two terminals of the liquid crystal (the AC voltage is taken a zero reference potential with VCOM), that is, the data driving voltage has both positive polarity and negative polarity.

Thus, the operation process of the liquid crystal panel, such as a thin film transistor liquid crystal display, TFT LCD, is to continuously charge the pixel electrode from the positive polarity to the negative polarity and then charge from the negative polarity to the positive polarity, and this charging process must be completed within a limited time when each row of the TFT is turned on. As the resolution and refresh rate of the liquid crystal panel become higher and higher, the time to turn on each scanning line is greatly shortened, and the problem of insufficient charging time (storage capacitor Cst and liquid crystal capacitor Clc) of the liquid crystal panel becomes more prominent, and therefore there is a problem of insufficient charging time.

There are two approaches to solving the problem of insufficient charging time in the conventional technology: pre-charge and charge sharing. In the pre-charge method, the gate electrode of the next row is opened in advance to pre-charge the data of the previous row to the next row, and the charge polarity of the next row is reversed in advance, thereby reducing the charging time of the liquid crystal panel. In the charge sharing method, according to the polarity inversion signal, in the blanking region before the polarity inversion, the data driver internally connects the adjacent odd data lines and the even data lines, and the parasitic capacitance on the two data lines is charge neutralized, so that the charging time of the liquid crystal panel is shortened. However, pre-charge is only applicable to column inversion or frame inversion, and charge sharing is only applicable to inverting modes where the polarity reversal frequency is high, such as point inversion.

### SUMMARY OF THE INVENTION

To overcome the shortcomings of the conventional technology, an exemplary embodiment of the present application provides a thin film transistor liquid crystal panel capable of shortening a charging time of a liquid crystal panel and reducing power consumption and temperature of a data driver device.

According to an exemplary embodiment of the present application, an aspect of the present application provides a liquid crystal panel including: a. plurality of gate lines extending in the row direction and are parallel to each other; a plurality of data lines extending in the column direction and are parallel to each other, wherein the gate line and the data line are cross disposed; a sub-pixel is disposed at the intersection of each gate line and each data line; a switching thin-film transistor disposed between each of the odd sub-pixels and the even sub-pixels adjacent to each other on each row; the odd sub-pixels is the sub-pixels located in the odd columns; the even sub-pixels is the sub-pixels located in the even columns; and wherein a gate electrode of the switching TFT is connected to the corresponding gate line of the previous pixel row, a drain electrode of the switching TFT is connected to the corresponding odd sub-pixel, and a source electrode of the switching TFT is connected to the corresponding even sub-pixel.

Further, the sub-pixel including: a thin film transistor, a liquid crystal capacitor, and a storage capacitor, a gate electrode of the thin film transistor is connected to the corresponding gate line, a source electrode of the thin film transistor is connected to the corresponding data line, and the liquid crystal capacitor and the storage capacitor are parallel connected and connected to a drain electrode of the thin film transistor.

Further, the drain electrode of the thin film transistor is connected to the parallel connected liquid crystal capacitor and the storage capacitor of the corresponding odd sub-pixel, the source electrode of the thin film transistor is connected to the parallel connected liquid crystal capacitor and the storage capacitor of the corresponding even sub-pixel.

Further, the voltage of the nth gate line is switched from a low electrical level to a high electrical level, held for a specific period of time and switched to the low electrical level, in the time of switching to the low electrical level, the voltage of the n+1th gate line is switched from the low electrical level to the high electrical level and held for a specific period of time, while the voltage of the nth gate line is the high electrical level, the switching TFT connected to the n+1th gate line is turned on, and makes the voltage of the n+1th gate line is the low electrical level, the charge of the storage capacitor and the liquid crystal capacitor of the even sub-pixels and the odd sub-pixels adjacent to each other of the n+1th row are mutually neutralized.

Further, the thin-film transistor and/or the switching thin-film transistor are amorphous silicon thin-film transistor or low temperature polysilicon thin-film transistor.

According to an exemplary embodiment of the present application, the other aspect of the present application provides a liquid crystal display apparatus, including a liquid crystal panel, a gate driver and a data driver, wherein the liquid crystal panel including: a plurality of gate lines extending in the row direction and are parallel to each other; the plurality of the gate lines are connected to the gate driver; a plurality of data lines extending in the column direction and are parallel to each other, wherein the gate line and the data line are cross disposed; the plurality of data lines are connected to the data driver; a sub-pixel is disposed at the intersection of each gate line and each data line; a switching thin-film transistor disposed between each of the odd sub-pixels and the even sub-pixels adjacent to each other on each row; the odd sub-pixels is the sub-pixels located in the odd columns; the even sub-pixels is the sub-pixels located in the even columns; and wherein a gate electrode of the switching TFT is connected to the corresponding gate line of the previous pixel row, a drain electrode of the switching TFT is connected to the corresponding odd sub-pixel, and a source electrode of the switching TFT is connected to the corresponding even sub-pixel.

Further, the voltage of the nth gate line provided by the gate driver is switched from a low electrical level to a high electrical level, held for a specific period of time and switched to the low electrical level, in the time of switching to the low electrical level, the voltage of the n+1th gate line provided by the gate driver is switched from the low electrical level to the high electrical level and held for a specific period of time, while the voltage of the nth gate line provided by the gate driver is the high electrical level, the switching TFT connected to the n+1th gate line is turned on, and makes the voltage of the n+1th gate line is the low electrical level, the charge of the storage capacitor and the liquid crystal capacitor of the even sub-pixels and the odd sub-pixels adjacent to each other of the n+1th row are mutually neutralized.

The liquid crystal panel provided according to an exemplary embodiment of the present application can shorten the charging time of the liquid crystal panel and reduce the power consumption and temperature of the data driver.

Additional aspects and/or advantages of the invention will be set forth in part in the description which follows and, in part, will be apparent from the description, or can be learned by practice of the invention.

### BRIEF DESCRIPTION OF THE DRAWINGS

In order to more clearly illustrate the embodiments of the present application or prior art, the following figures will be described in the embodiments are briefly introduced. It is obvious that the drawings are merely some embodiments of the present application, those of ordinary skill in this field can obtain other figures according to these figures without paying the premise.

FIG. 1 is a schematic diagram illustrating a liquid crystal panel according to an exemplary embodiment of the present application; and

FIG. is a charging timing diagram of the liquid crystal panel according to an exemplary embodiment of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts obtained should be considered within the scope of protection of the present application.

Specifically, the terminologies in the embodiments of the present application are merely for describing the purpose of the certain embodiment, but not to limit the invention. Examples and the claims be implemented in the present application requires the use of the singular form of the book “an”, “the” and “the” are intend to include most forms unless the context clearly dictates otherwise. It should also be understood that the terminology used herein that “and/or” means and includes any or all possible combinations of one or more of the associated listed items.

The liquid crystal panel described herein includes a plurality of pixels, each pixel includes a plurality of sub-pixels of colors, such as, for example only, the plurality of sub-pixels of colors can be red sub-pixels, green sub-pixels and blue sub-pixels.

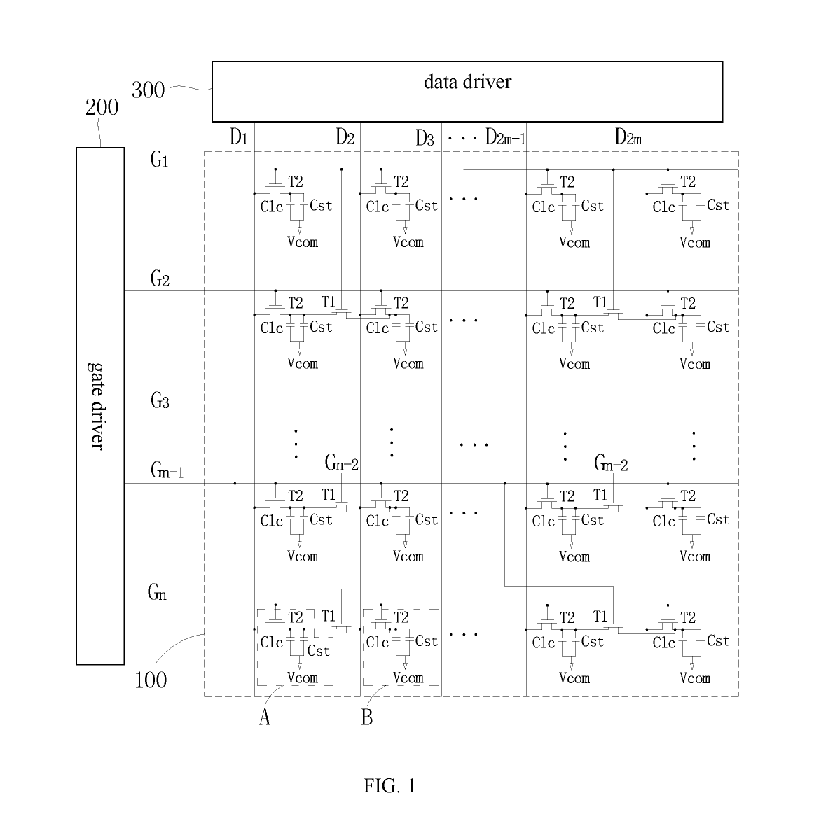

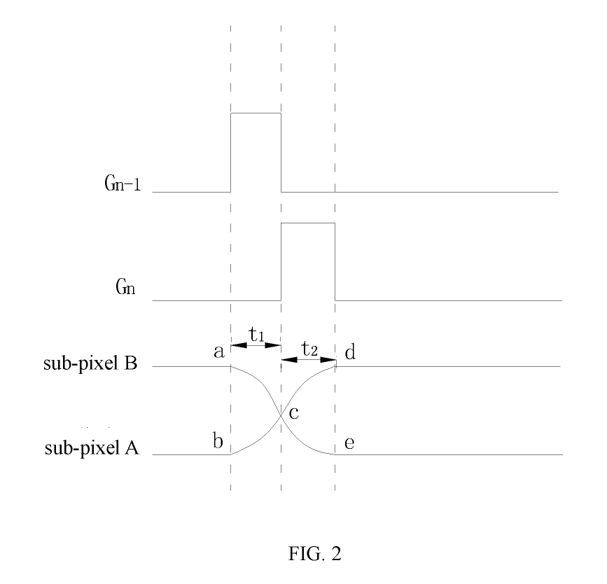

FIG. 1 is a schematic diagram showing a liquid crystal display (LCD) according to exemplary embodiment of the present application.

Referring to FIG. 1, the LCD includes a liquid crystal panel assembly 100, a gate driver 200, and a data driver 300, both of which are connected to the liquid crystal panel assembly 100. The liquid crystal panel assembly 100 includes a plurality of gate lines Gto Gₙ for transmitting gate signals, a plurality of data lines D₁ to D₂ₘ for transmitting data signals, a plurality of sub-pixels, and a plurality of switching thin-film transistors (TFT) T1.

The gate lines G₁ to Gₙ extend in the row direction and are parallel to each other; the data lines D₁ to D₂ₘ extend in the column direction and are parallel to each other. Each gate line and each data line are arranged to be crossed and isolated from each other. A sub-pixel is disposed at the intersection of each gate line and each data line. Each sub-pixel includes a thin film transistor T2 a liquid crystal capacitor Clc, and a storage capacitor Cst. Each thin film transistor T2 is connected to a corresponding gate line and a corresponding data line. The liquid crystal capacitor Clc and the storage capacitor Cst are connected in parallel to the thin film transistor T2.

A switching thin-film transistor T1 is disposed between each of the odd sub-pixels and the even sub-pixels adjacent to each other on a pixel row (or row). The gate electrode G of the switching TFT T1 is connected to the gate line of the previous pixel row, the drain electrode is connected to the storage capacitor Cst and the liquid crystal capacitor Clc of the odd sub-pixel, and the source electrode is connected to the storage capacitor Cst and the liquid crystal capacitor Clc of the even sub-pixel. The odd sub-pixels refer to sub-pixels located in the odd columns. The even sub-pixels refer to sub-pixels located in the even columns. The gate driver 200 is connected to the gate lines G₁ to Gₙ of the liquid crystal panel assembly 100 to apply a gate signal (which is a voltage signal composed of a high electrical level voltage signal and a low electrical level voltage signal) to the gate lines G₁ to Gₙ.

The data driver 300 is connected to the data lines D₁ to D₂ₘ of the liquid crystal panel assembly 100 and applies data voltages to each sub-pixel.

The difference between the data voltage applied to each sub-pixel and the common voltage Vcom can be interpreted as a voltage by which the liquid crystal capacitor Clc of each sub-pixel is charged, that is the pixel voltage. The arrangement of the liquid crystal molecules in the liquid crystal layer varies according to the magnitude of the pixel voltage, and thus the polarity of the light transmitted through the liquid crystal layer can be varied, resulting in a change in transmittance of the liquid crystal layer.

Hereinafter, the charging process of the odd sub-pixels and the even sub-pixels adjacent to each other according to the embodiment of the present application is described.

FIG. 2 is a charging timing diagram of the liquid crystal panel according to an exemplary embodiment of the present application.

Combining the illustrations of FIGS. 1 and 2, the charging process of the sub-pixel A and the sub-pixel B connected to the gate line Gₙ is taken as an example:

In the first period t₁, the gate driver 200 applies a high electrical level signal to the gate line Gₙ₋₁, since the gate electrode of the switching thin-film transistor T1 between the sub-pixel A and the sub-pixel B is connected to the gate line Gₙ₋₁, the switching thin film transistor T1 between the sub-pixel A and the sub-pixel B is turned on, the charges of the storage capacitor Cst and the liquid crystal capacitor Clc of the sub-pixel A and the sub-pixel B are mutually neutralized, and the sub-pixel B is lowered from an a point with high potential of the positive polarity to a c point, the sub-pixel A is raised to the c point from a b point with low potential of the negative polarity, the charge neutralize each other.

In the second period t₂, the gate driver 200 applies a high electrical level signal to the gate line Gₙ, the thin film transistor T2 of all of the sub-pixels connected to the gate line Gₙ is turned on, a data voltage is applied to all of the sub-pixels connected to the gate line Gₙ by the data driver 300, and to charge all of the sub-pixels connected to the gate line Gₙ. Due to the charge neutralization in the first time period t₁, the second time period t₂, the thin film transistor T2 of the sub-pixel A and the sub-pixel B can be charged from a voltage level closer to the target sub-pixel, i.e., the sub-pixel is charged from the c point to a e point, the sub-pixel A is charged from the c point to a d point, therefore the charging time can reduced. In addition, the charge neutralizes of the sub-pixel to each other can reduce the power consumption and temperature of the data driver 300.

According to an exemplary embodiment of the present application, each gate line is sequentially turned on in row order, that is, the voltage of the gate line Gₙ₋₁ of the liquid crystal panel can be switched from the low electrical level to the high electrical level, held for a specific period of time and switched to the low electrical level, in the time of switching to the low electrical level, the voltage of the gate line Gₙ is switched from the low electrical level to the high electrical level and held for a specific period of time, while the voltage of the gate line of the current pixel row is at the high electrical level, the switching TFT of the next row is turned on, and makes the voltage of the gate line of the next pixel row is at the low electrical level, i.e., before the voltage is actually loading to the sub-pixel, the charge of the storage capacitor Cst and the liquid crystal capacitor Clc of the even sub-pixels and the odd sub-pixels adjacent to each other of the gate line of next pixel row are mutually neutralized, so that the charging time of the liquid crystal panel can be shortened and the power consumption and temperature of the data driver can be reduced.

Further, the above-described method according to the present application can be implemented as computer code in a computer-readable recording medium. The computer code can be implemented by a person skilled in the art in accordance with the description of the method described above. The above-described method of the present application is implemented when the computer code is executed in a computer.

In addition, the respective units in the driving apparatus of the liquid crystal panel according to the exemplary embodiment of the present application can be implemented as hardware components. Depending on the processing performed by the various units defined, one skilled in the art may implement the various units using, for example, a field programmable gate array (FPGA) or application specific integrated circuit (ASIC).

Above are embodiments of the present application, which does not limit the scope of the present application. Any modifications, equivalent replacements or improvements within the spirit and principles of the embodiment described above should be covered by the protected scope of the invention.

What is claimed is:

1. A liquid crystal panel, wherein the liquid crystal panel comprising:
a plurality of gate lines extending in the row direction and are parallel to each other;
a plurality of data lines extending in the column direction and are parallel to each other, wherein the gate line and the data line are cross disposed;
a sub-pixel is disposed at the intersection of each gate line and each data line;
a switching thin-film transistor disposed between each of the odd sub-pixels and the even sub-pixels adjacent to each other on each row; the odd sub-pixels is the sub-pixels located in the odd columns; the even sub-pixels is the sub-pixels located in the even columns; and
wherein a gate electrode of the switching TFT is connected to the corresponding gate line of the previous pixel row, a drain electrode of the switching TFT is connected to the corresponding odd sub-pixel, and a source electrode of the switching TFT is connected to the corresponding even sub-pixel.

2. The liquid crystal panel according to claim 1, wherein the sub-pixel comprising:
a thin film transistor, a liquid crystal capacitor, and a storage capacitor, a gate electrode of the thin film transistor is connected to the corresponding gate line, a source electrode of the thin film transistor is connected to the corresponding data line, and the liquid crystal capacitor and the storage capacitor are parallel connected and connected to a drain electrode of the thin film transistor.

3. The liquid crystal panel according to claim 2, wherein the drain electrode of the thin film transistor is connected to the parallel connected liquid crystal capacitor and the storage capacitor of the corresponding odd sub-pixel, the source electrode of the thin film transistor is connected to the parallel connected liquid crystal capacitor and the storage capacitor of the corresponding even sub-pixel.

4. The liquid crystal panel according to claim 3, wherein the voltage of the nth gate line is switched from a low electrical level to a high electrical level, held for a specific period of time and switched to the low electrical level, in the time of switching to the low electrical level, the voltage of the n+1th gate line is switched from the low electrical level to the high electrical level and held for a specific period of time, while the voltage of the nth gate line is the high electrical level, the switching TFT connected to the n+1th gate line is turned on, and makes the voltage of the n+1th gate line is the low electrical level, the charge of the storage capacitor and the liquid crystal capacitor of the even sub-pixels and the odd sub-pixels adjacent to each other of the n+1th row are mutually neutralized.

5. The liquid crystal panel according to claim 1, wherein the thin-film transistor and/or the switching thin-film transistor are amorphous silicon thin-film transistor or low temperature polysilicon thin-film transistor.

6. The liquid crystal panel according to claim 2, wherein the thin-film transistor and/or the switching thin-film transistor are amorphous silicon thin-film transistor or low temperature polysilicon thin-film transistor.

7. The liquid crystal panel according to claim 3, wherein the thin-film transistor and/or the switching thin-film transistor are amorphous silicon thin-film transistor or low temperature polysilicon thin-film transistor.

8. The liquid crystal panel according to claim 4, wherein the thin-film transistor and/or the switching thin-film transistor are amorphous silicon thin-film transistor or low temperature polysilicon thin-film transistor.

9. A liquid crystal display apparatus, comprising a liquid crystal panel, a gate driver and a data driver, wherein the liquid crystal panel comprising:
a plurality of gate lines extending in the row direction and are parallel to each other; the plurality of the gate lines are connected to the gate driver;
a plurality of data lines extending in the column direction and are parallel to each other, wherein the gate line and the data line are cross disposed; the plurality of data lines are connected to the data driver;
a sub-pixel is disposed at the intersection of each gate line and each data line;
a switching thin-film transistor disposed between each of the odd sub-pixels and the even sub-pixels adjacent to each other on each row; the odd sub-pixels is the sub-pixels located in the odd columns; the even sub-pixels is the sub-pixels located in the even columns; and
wherein a gate electrode of the switching TFT is connected to the corresponding gate line of the previous pixel row, a drain electrode of the switching TFT is connected to the corresponding odd sub-pixel, and a source electrode of the switching TFT is connected to the corresponding even sub-pixel.

10. The liquid crystal display apparatus according to claim 9, wherein the sub-pixel comprising:
a thin film transistor, a liquid crystal capacitor, and a storage capacitor, a gate electrode of the thin film transistor is connected to the corresponding gate line, a source electrode of the thin film transistor is connected to the corresponding data line, and the liquid crystal capacitor and the storage capacitor are parallel connected and connected to a drain electrode of the thin film transistor.

11. The liquid crystal display apparatus according to claim 10, wherein the drain electrode of the thin film transistor is connected to the parallel connected liquid crystal capacitor and the storage capacitor of the corresponding odd sub-pixel, the source electrode of the thin film transistor is connected to the parallel connected liquid crystal capacitor and the storage capacitor of the corresponding even sub-pixel.

12. The liquid crystal display apparatus according to claim 11, wherein the voltage of the nth gate line provided by the gate driver is switched from a low electrical level to a high electrical level, held for a specific period of time and switched to the low electrical level, in the time of switching to the low electrical level, the voltage of the n+1th gate line provided by the gate driver is switched from the low electrical level to the high electrical level and held for a specific period of time, while the voltage of the nth gate line provided by the gate driver is the high electrical level, the switching TFT connected to the n+1th gate line is turned on, and makes the voltage of the n+1th gate line is the low electrical level, the charge of the storage capacitor and the liquid crystal capacitor of the even sub-pixels and the odd sub-pixels adjacent to each other of the n+1th row are mutually neutralized.

13. The liquid crystal display apparatus according to claim 9, wherein the thin-film transistor and/or the switching thin-film transistor are amorphous silicon thin-film transistor or low temperature polysilicon thin-film transistor.

14. The liquid crystal display apparatus according to claim 10, wherein the thin-film transistor and/or the switching thin-film transistor are amorphous silicon thin-film transistor or low temperature polysilicon thin-film transistor.

15. The liquid crystal display apparatus according to claim 11, wherein the thin-film transistor and/or the switching thin-film transistor are amorphous silicon thin-film transistor or low temperature polysilicon thin-film transistor.

16. The liquid crystal display apparatus according to claim 12, wherein the thin-film transistor and/or the switching thin-film transistor are amorphous silicon thin-film transistor or low temperature polysilicon transistor.
